(19) United States
(12) Patent Application Publication
(10) Pub. No.: US 2011/0018558 A1
(43) Pub. Date: Jan. 27, 2011

(54) ELECTROSTATIC SENSOR

(75) Inventors: Koichi Saito, Kyoto (JP); Masaya Hirakawa, Kyoto (JP); Yuji Kobayashi, Kyoto (JP)

Correspondence Address: CANTOR COLBURN LLP, 20 Church Street, 22nd Floor, Hartford, CT, 06103, US

(73) Assignee: ROHM CO., LTD., Ukyo-Ku, Kyoto (JP)

(21) Appl. No.: 12/935,866

(22) PCT Filed: Apr. 1, 2009
(86) PCT No.: PCT/JP2009/001537

§ 371 Date: Sep. 30, 2010

(30) Foreign Application Priority Data
Apr. 1, 2008 (JP) 2008-094883

(51) Int. Cl. G01R 27/26

(52) U.S. Cl. 324/676

(57) ABSTRACT

Multiple sensor capacitors Cd are respectively assigned to multiple buttons B1 through B3. Each of the multiple sensor capacitors is assigned to one of the multiple channels. A capacitance detection unit detects the combined capacitance of the sensor capacitors each of which is assigned to the corresponding one of the multiple channels. A comparison unit compares the combined capacitance detected by the capacitance detection unit for each channel with a predetermined threshold value, and converts the comparison results into binary digital signals in increment of channels. A decoder decodes the binary digital signals output in increments of channels from the comparison unit, and judges whether each switch is in the ON state or the OFF state.

This is a U.S. national stage application of International Application No. PCT/JP2009/001537, filed on 1 Apr. 2009. Priority under 35 U.S.C. §119(a) and 35 U.S.C. §365(b) is claimed from Japanese Application No. JP2008-094883, filed 1 Apr. 2008, the disclosure of which is also incorporated herein by reference.

### FIELD OF THE INVENTION

The present invention relates to an electrostatic sensor using a change in capacitance of an electrostatic capacitor.

### DESCRIPTION OF THE RELATED ART

In recent years, in many cases, electronic devices such as computers, cellular phone terminals, PDAs (Personal Digital Assistants), etc., include an input device which allows the user to operate the electronic device by using a finger apply pressure to the input device. Known examples of such input devices include a joystick, touch pad, etc.

Such an input device detects and analyzes the input from the user using a mechanism in which the distance between the electrodes in a pair of opposing electrodes changes due to the pressure thus applied, and accordingly, electrostatic capacitance changes. For example, such an input device using a change in electrostatic capacitance is disclosed in Patent document 1.

### [Patent Document No. 1]

Japanese Patent Application Laid Open No. 2001-325858

### SUMMARY OF THE INVENTION

The present invention has been made in view of such a situation. Accordingly, it is an exemplary purpose thereof to provide a technique for detecting a change in electrostatic capacitance so as to perform various kinds of signal processing.

An embodiment of the present invention relates to an electrostatic sensor. The electrostatic sensor comprises: multiple switches; multiple sensor capacitors assigned to each of the multiple switches; and a control circuit which judges based upon the capacitance values of the multiple sensor capacitors whether each of the multiple switches is in the ON state or the OFF state. With such an arrangement, each of the multiple sensor capacitors is assigned to one of multiple channels. Furthermore, the control circuit comprises: a capacitance detection unit which detects the combined capacitance of the sensor capacitors assigned to each of the multiple channels; a comparison unit which compares, in increments of channels, the combined capacitance detected by the capacitance detection unit with a predetermined threshold value, and converts the comparison results into binary digital signals in increments of channels; and a decoder which decodes the binary digital signals output in increments of channels from the comparison unit, and judges whether each switch is in the ON state or the OFF state.

With such an embodiment, judgment is made whether a given switch is in the ON state or the OFF state, based upon the pressure state applied to the multiple sensor capacitors. Thus, such an arrangement prevents false detection of the ON/OFF state of each switch.

It is to be noted that any arbitrary combination or rearrangement of the above-described structural components and so forth is effective as and encompassed by the present embodiments.

Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a block diagram which shows a configuration of an electrostatic sensor according to a first embodiment;

FIG. 2 is a diagram which shows a terminal table for a control circuit shown in FIG. 1;

FIG. 3 is a pin layout diagram for the control circuit shown in FIG. 1;

FIG. 4 is a diagram which shows a table of detection conditions used for detecting a gesture in each mode;

FIG. 5 is a block diagram which shows the configuration of a data correction processing unit;

FIGS. 6A and 6B are diagrams which show the operation of the data correction processing unit;

FIG. 7 is a diagram which shows a register map for the control circuit shown in FIG. 1;

FIG. 8 is a block diagram which shows the configuration of the data correction processing unit of the control circuit according to a second embodiment;

FIGS. 9A and 9B are diagrams which show the layout of division sensor capacitors and threshold judgment using division sensor capacitors; and

FIGS. 10A through 10D are diagrams which show judgment processing performed by a simultaneously pressed button judgment circuit.

### DETAILED DESCRIPTION OF THE INVENTION

Description will be made below regarding preferred embodiments according to the present invention with reference to the drawings. The same or similar components, members, and processes are denoted by the same reference numerals, and redundant description thereof will be omitted as appropriate. The embodiments have been described for exemplary purposes only, and are by no means intended to restrict the present invention. Also, it is not necessarily essential for the present invention that all the features or a combination thereof be provided as described in the embodiments.

In the present specification, the state represented by the phrase “the member A is connected to the member B” includes a state in which the member A is indirectly connected to the member B via another member that does not affect the electric connection therebetween, in addition to a state in which the member A is physically and directly connected to the member B. In the same way, the state represented by the phrase “the member C is provided between the member A and the member B” includes a state in which the member A is indirectly connected to the member C, or the member B is indirectly connected to the member C via another member that does not affect the electric connection therebetween, in addition to a state in which the member A is directly connected to the member C, or the member B is directly connected to the member C.

### First Embodiment

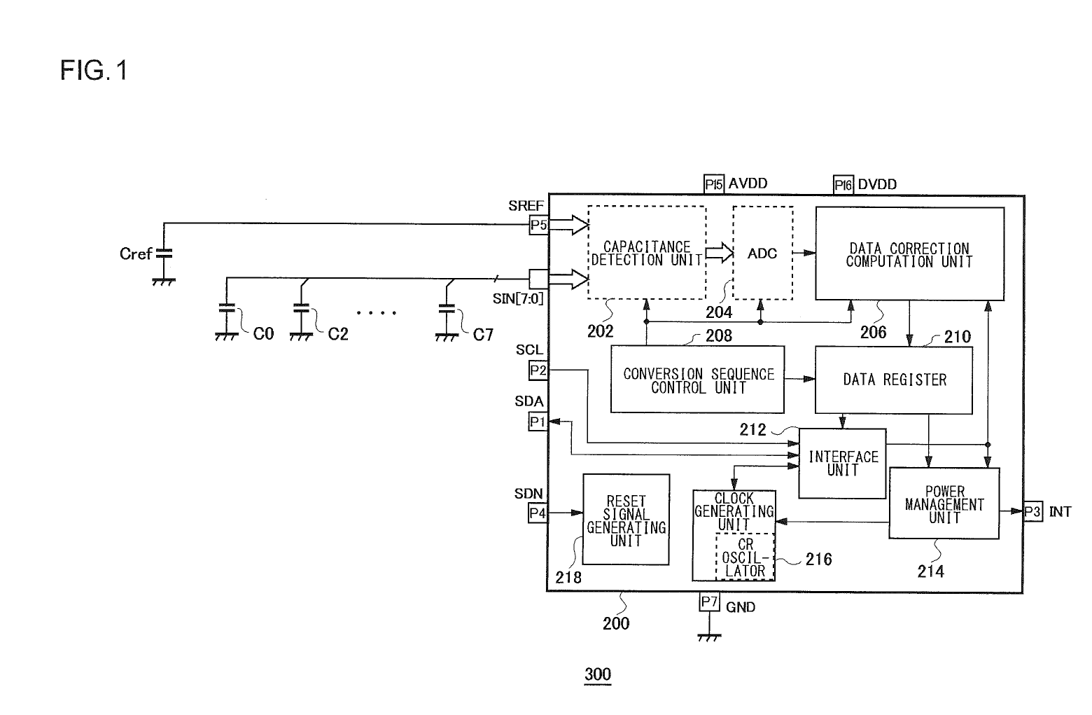

FIG. 1 is a block diagram which shows a configuration of an electrostatic sensor 300 according to a first embodiment. The electrostatic sensor 300 includes multiple variable capacitors (which will be referred to as “sensor capacitors”) C0 through C7, and a control circuit 200.

Each sensor capacitor includes a pair of two opposing electrodes. The capacitance of the sensor capacitor changes according to changes in the distance between these two electrodes due to external pressure. The control circuit 200 measures the capacitance of each of the electrostatic capacitors C0 through C7, and detects the pressure state applied to each electrode pair based upon the measurement values thus measured. Furthermore, the control circuit 200 performs signal processing as necessary, and outputs information with respect to the pressure states to an external circuit.

Description will be made below in the embodiment regarding an arrangement in which the control circuit 200 is provided with an 8-channel sensor input unit. Also, the present invention can be applied to an arrangement in which there are 16 channels or another number of channels.

The control circuit 200 includes a 1st pin P1 through a 16th pin P16 as input/output terminals. Furthermore, the control circuit 200 includes a capacitance detection unit 202, an A/D converter 204, a data correction processing unit 206, a conversion sequence control unit 208, a data register 210, an interface unit 212, a power management unit 214, a clock generating unit 216, and a reset signal generating unit 218.

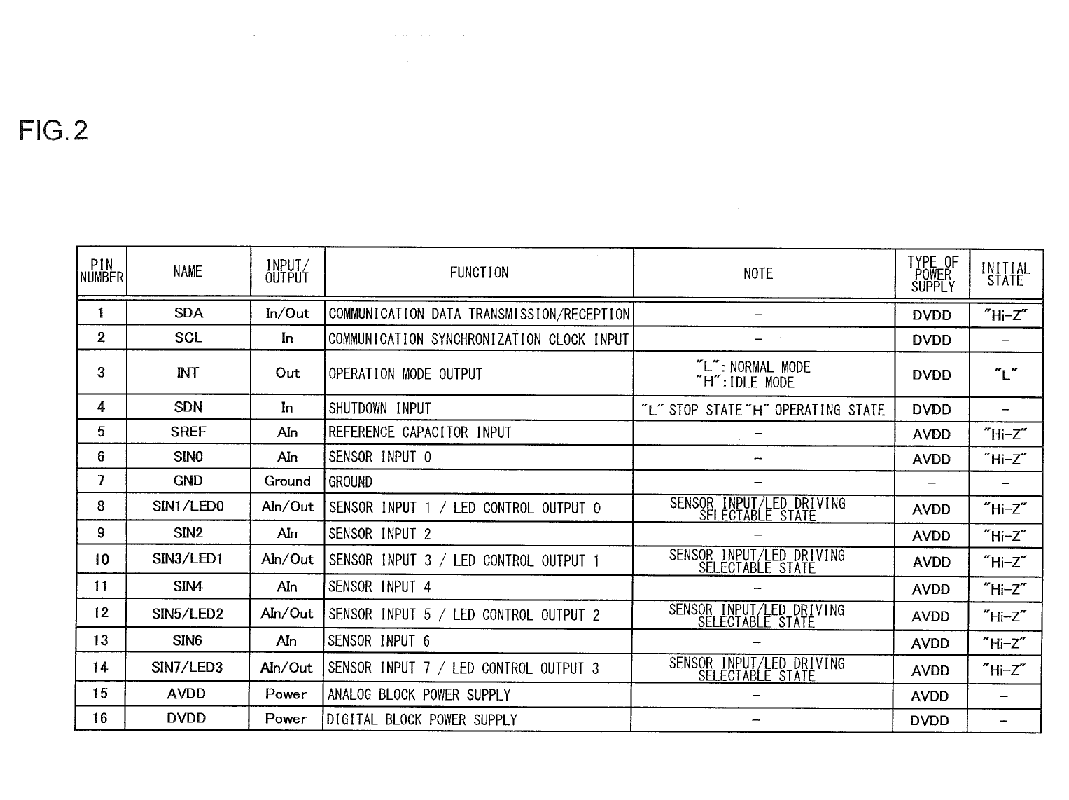

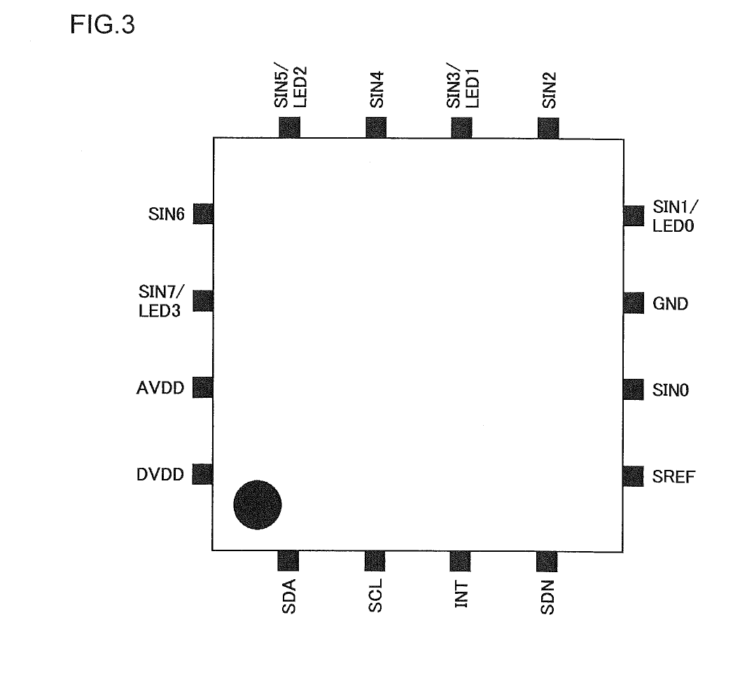

FIG. 2 is a diagram which shows a terminal table for the control circuit 200 shown in FIG. 1. FIG. 3 is a pin layout diagram for the control circuit 200 shown in FIG. 1.

Referring to FIG. 1, a power supply voltage AVDD for an analog circuit block of the control circuit 200 is supplied to the 15th pin P15. A power supply voltage DVDD for a digital circuit block of the control circuit 200 is supplied to the 16th pin P16. The 7th pin is connected to a ground voltage GND.

The 1st pin P1 and the 2nd pin P2 are connected to an external processor which is not shown in FIG. 1. The interface unit 212 is provided in order to enable serial data communication between the control circuit 200 and the external processor (which will also be referred to as the “host processor”) via an I²C (Inter IC) bus. Serial data SDA is transmitted/received via the 1st pin P1. A synchronization clock SCL is input via the 2nd pin P2.

The power management unit 214 is a block which manages a power supply for the control circuit 200. The power management unit 214 outputs data INT, which indicates the operation mode of the control circuit 200, to an external circuit via the 3rd pin P3. The data INT also functions as an interrupt signal INT which is a notice of a change in capacitance detection (wakeup notice), which is used as a start-up signal for the host processor. In a case in which such a change in capacitance has not been detected for a predetermined time period, the power management unit 214 automatically transits to an idle mode in which the power management unit 214 performs intermittent driving operation.

The following modes are switched by power management.

### 1. Normal Mode

The normal mode is a normal operation state. The operation state pin INT is set to the low level (L).

### 2. Idle Mode

The idle mode is a state in which intermittent operation is performed. If the state in which operation has not been performed in the normal mode (the state in which an operation has not been detected) continues for a predetermined time period, sensor offset calibration is executed, following which the mode transits to the idle mode. If an operation by the user (via a finger) is detected during the idle mode, the mode is returned to the normal mode. If the intermittent operation mode is disabled, the detection step is always performed in the same way as in the normal mode. The operation state pin INT is set to the high level (H).

### 3. Shutdown Mode

The shutdown mode is a state in which the operations of all the analog circuits and digital circuits are stopped. When an SDN terminal is set to the low level (L), the mode transits to the shutdown mode. When the SDN terminal is switched to the high level (H), the mode is returned to the normal mode.

### 4. Calibration Mode

The calibration mode is a mode in which the difference in capacitance between a reference capacitance Cref and the capacitance Ci of each channel is detected so as to automatically execute offset adjustment.

When pressure has not been detected by any of the sensors, the mode transits to the idle mode, and the operation state pin INT is switched to the high level. The host processor does not need to access the control circuit 200 in the idle mode. Thus, such an arrangement suitably idles the host processor according to the state of the pin INT.

A shutdown signal SDN from an external circuit can be input to the reset signal generating unit 218 via the 4th pin P4. The reset signal generating unit 218 initializes the operation of the control circuit 200 according to the shutdown signal SDN.

The clock generating unit 216 uses a clock generated by a built-in CR oscillator as a system clock that it supplies to other blocks of the control circuit 200.

The 5th pin is connected to a reference capacitor Cref. The capacitance of the reference capacitor Cref is maintained at a constant value independent of the user's input operation. The 6th pin P6 and from the 8th pin P8 through the 14th pin P14 are connected to the sensor capacitors C0 through C7, respectively. That is to say, these pins function as the sensor input terminals SIN0 through SIN7.

It should be noted that each of the 8th pin P8, 10th pin P10, 12th pin P12, and 14th pin P14, which correspond to the channels 1, 3, 5, and 7, respectively, can be connected to an LED (Light Emitting Diode), instead of being connected to a sensor capacitor. In a case in which the respective pins are connected to LEDs, the 8th pin P8, 10th pin P10, 12th pin P12, and 14th pin P14 are referred to as LED control outputs LED0, LED1, LED2, and LED3, respectively. In a case in which the LEDs are connected, an unshown LED driver included within the control circuit 200 as a built-in component is switched to the active state, which controls the luminance of the LEDs. Furthermore, monitoring of the sensor capacitor is disabled for each channel connected to an LED.

The capacitance detection unit 202 includes: an interface circuit which selects one sensor capacitor from among the sensor capacitors C0 through C7 which are capacitance/voltage conversion targets; and a C/V conversion circuit which performs capacitance/voltage conversion (C/V conversion) in which the capacitance of the sensor capacitor Ci (i=0 to 7) thus selected is converted into voltage. For example, the C/V conversion circuit converts the difference in capacitance between each sensor capacitor Ci and the reference capacitor Cref into voltage, thereby detecting the change in capacitance. The technique which has been proposed by the present applicant (Japanese Patent Application Laid Open No. 2006-253764) can be suitably employed for such a C/V conversion circuit. The capacitance detection unit 202 selects one from among the multiple sensor capacitors C0 through C7 in a time-sharing manner, and outputs the voltages that correspond to the respective capacitance values in a sequential manner.

It should be noted that multiple C/V conversion circuits may be included within the capacitance detection unit 202. With such an arrangement, the voltages that correspond to the capacitance values of the multiple sensor capacitors are output in parallel.

The A/D converter 204 converts the capacitance value of the sensor capacitor Ci, which has been converted into voltage, into a digital value. The A/D converter 204 has 10-bit resolution with the analog power supply voltage AVDD as a reference voltage.

The conversion sequence control unit 208 generates a timing signal according to which the interface circuit of the capacitance detection unit 202 selects the sensor capacitor Ci and a timing signal according to which the A/D converter 204 performs A/D conversion of the voltage that corresponds to the capacitance value.

As necessary, the data correction processing unit 206 corrects the data (which will be referred to as the “detection data Di” hereafter) that correspond to the capacitance values of the sensor capacitors Ci thus subjected to the C/V conversion and A/D conversion. Furthermore, the data correction processing unit 206 performs processing such as threshold comparison, gesture detection, etc., according to each application, so as to convert the detection data into a predetermined data format.

The data register 210 holds, in increments of the sensor capacitors Ci, the data thus generated by the data correction processing unit 206. Furthermore, the data register 210 holds control data for controlling the operation of the control circuit 200.

The above is the overall configuration of the control circuit 200. Next, description will be made regarding a gesture detection function provided by the data correction processing unit 206.

The gesture detection function is a function of detecting whether or not predetermined buttons are switched on in a predetermined order. Specifically, the control circuit 200 is capable of assigning a maximum of four sensor input terminals SIN0, SIN2, SIN3, and SIN6, which correspond to the channels 0, 2, 4, and 6, for the gesture detection described below. The sensors to be assigned to the gesture detection are set by respective registers (EN, described later).

The gesture detection can be switched between a strict detection mode and a redundant mode. The strict detection mode is a mode in which only a case in which the four sensor channels are pressed in a perfectly correct order is detected as a gesture. The redundant mode is a mode in which even a case in which one of the four channels is skipped when the channels are pressed is also detected as a gesture. Two patterns of gestures, i.e., a gesture obtained by pressing the channels in the forward direction and a gesture obtained by pressing the channels in the reverse direction, can be detected for each mode.

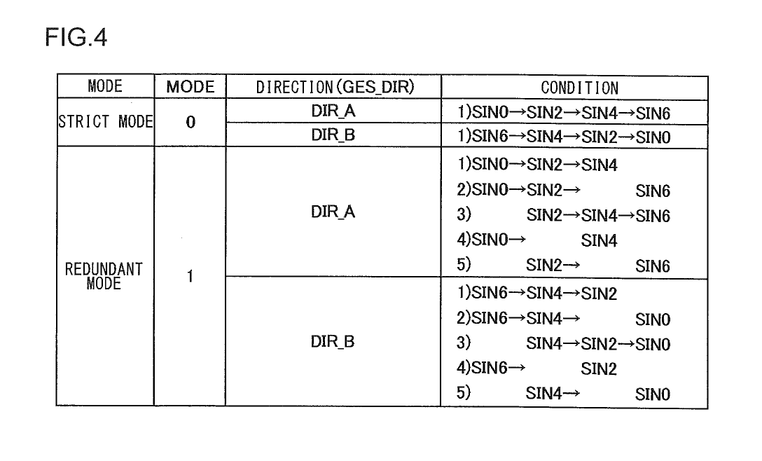

FIG. 4 is a diagram which shows a table of detection conditions used for detecting a gesture in each mode. FIG. 4 shows the conditions for an arrangement in which the four channels SIN0, SIN2, SIN3, and SING are used as the detection targets. In a case in which one channel is selected as an unavailable channel, the conditions with respect to the channel thus selected are redundant and should be ignored.

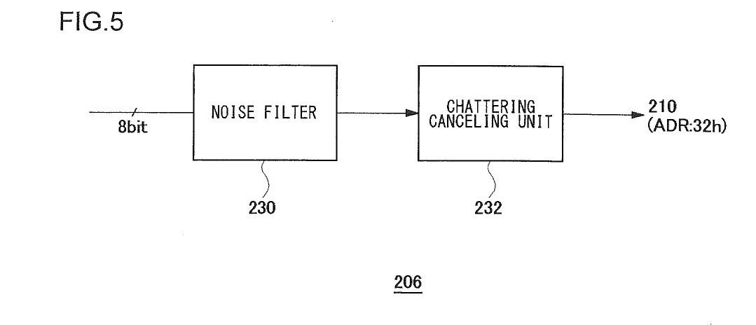

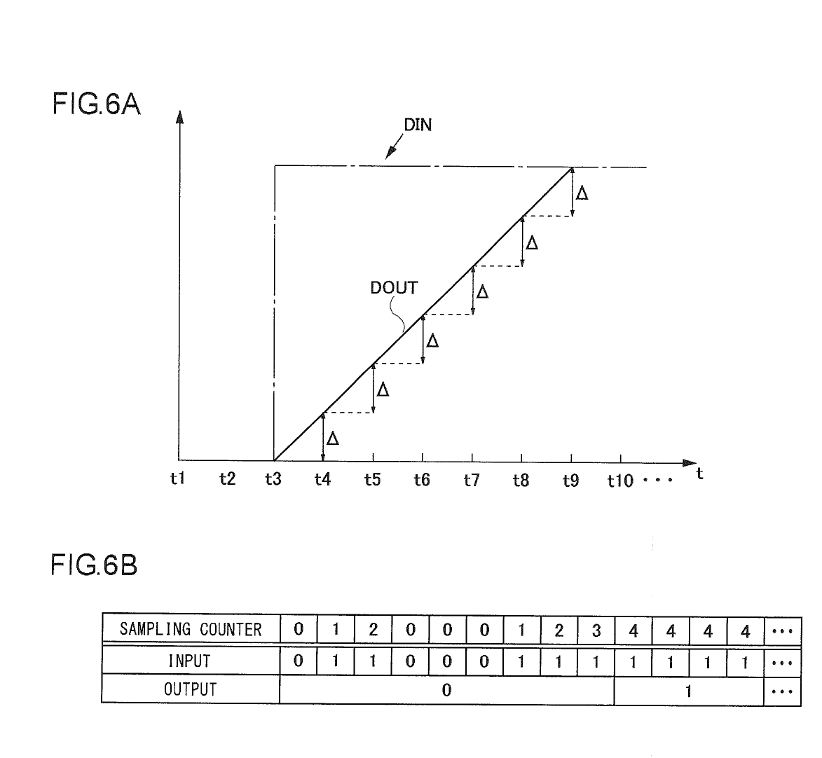

FIG. 5 is a block diagram which shows a configuration of the data correction processing unit 206. FIG. 6A and FIG. 6B are diagrams which show the operation of the data correction processing unit 206. The data correction processing unit 206 includes a noise filter 230 and a chattering canceling unit 232.

The noise filter 230 receives 8-bit data DIN which indicates the capacitance values of the sensor capacitors Ci from the A/D converter 204. The noise filter 230 clamps the difference between the output value DOUTⱼ output at the current point in time tᵢ and the output value DOUTⱼ₋₁ output at the previous point in time tᵢ₋₁ to a predetermined width Δ.

That is to say, when abs(DINⱼ-DOUTⱼ₋₁) is smaller than Δ, DOUTⱼ is set to DIN, and when abs (DINⱼ-DOUTⱼ₋₁) is greater than Δ, DOUTⱼ is set to DOUTⱼ₋₁±Δ.

FIG. 6A is a time wavelength diagram which shows the operation of the noise filter 230. The solid line indicates the output data DOUT of the noise filter 230, and the broken line indicates the input data DIN of the noise filter 230. The noise filter 230 limits the width of the change in the output data of the A/D converter 204. This reduces the responsiveness of the A/D converter 204, thereby enabling a reduction in noise.

The noise filter 230 is configured such that the function thereof can be switched according to the value of the input data DIN. That is to say, when the data Dⱼ is smaller than a predetermined threshold level (i.e., when the button is in the OFF state), the aforementioned function is executed so as to reduce the responsiveness of the button.

Conversely, when the data Dⱼ is greater than the predetermined threshold level (i.e., when the button is in the ON state), the following operation is performed. That is to say, when the data value increases, the input data is output as it is. Conversely, when the data value decreases, the width of the decrease is clamped to a predetermined value.

As described above, in a case in which it has been judged that the button is in the ON state based upon the data being equal to or greater than the threshold value, when the data changes in the increasing direction, the data is output as it is. On the other hand, when the data changes in the decreasing direction, the responsiveness is reduced. The data thus subjected to such processing by the noise filter 230 is compared with a threshold level (ON_TH or OFF_TH). Thus, such an arrangement prevents the judgment that the button is in the ON state or the OFF state from being alternately and repeatedly made due to fluctuation of the capacitance of the sensor capacitor around the threshold value.

Returning to FIG. 5, the chattering canceling unit 232 functions as a digital filter. The chattering canceling unit 232 receives, as input data, the data regarding whether each button is in the ON (1) state or the OFF (0) state. The chattering canceling unit 232 compares the data thus received with the previous data every time the data is updated. In a case in which a predetermined number of data values “1” (which are set by SAMP[3:0] described later) are consecutively input, the chattering canceling unit 232 judges that the sensor is in the ON state. For example, the chattering canceling unit 232 is configured as a counter that is incremented when “1” is input, and reset when “0” is input.

FIG. 6B is a diagram which shows multiple judgment processing performed by the chattering canceling unit 232. An arrangement is shown in the drawing in which the predetermined number is four.

The output of the chattering canceling unit 232 is written to a predetermined address (32h) in the data register 210.

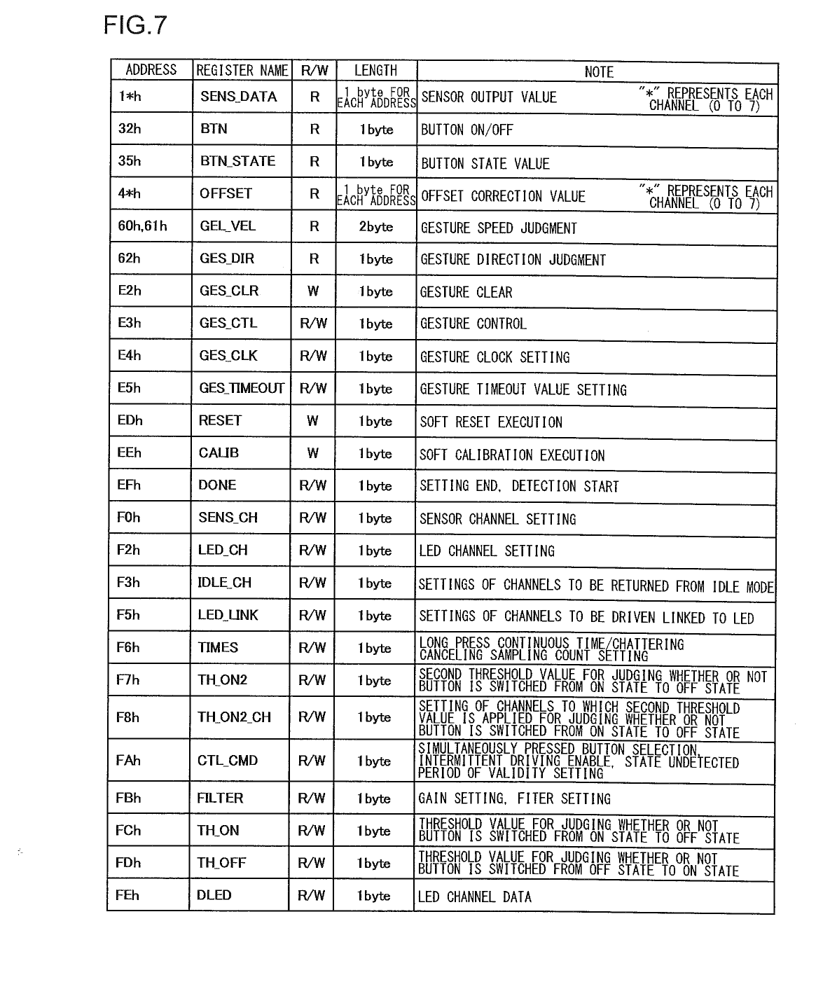

FIG. 7 is a diagram which shows a register map for the control circuit 200 shown in FIG. 1. Each address has a 1 byte (8 bit) configuration. Each bit will be indicated in descending order as Bit7 through Bit0. The register stores the following data for setting the operations and functions of the control circuit 200.

(1) Address 10h to 17h

Sensor Output Value (SENS_DATA)

The data which specifies the capacitance values of the sensor capacitors C0 through C7 are stored at the addresses 10h through 17h. A 1-byte (8 bit) configuration is assigned to each of the address 10h through 17h. The data is A/D converted by the A/D converter 204 into 10-bit digital data, following which the data thus A/D converted is offset corrected by the data correction processing unit 206. Subsequently, the upper 8 bits of the digital data thus offset corrected are stored. In a case in which the data correction processing unit 206 executes filtering processing described later, the data thus subjected to the filtering processing is stored. The initial values stored at the addresses 10h through 17h are (10000000) in binary. That is to say, the initial values are: Bit7=1; and Bit7 through Bit0=0.

(2) Address 32h

Button ON/OFF (BTN)

The data regions Bit7 through Bit0, provided as a 1 byte (8 bit) configuration at this address, store the data which indicates whether each button is in the ON state or the OFF state in an arrangement in which the sensor capacitors C0 through C7 are used as independent buttons. When a button is in the ON state, “1” is stored in the corresponding region. When a button is in the OFF state, “0” is stored in the corresponding region. The initial value is “0” for each button.

(3) Address 35h

Button State Value (BTN_STATE)

This address is used to hold the “button state value”. The data stored at this address is held until the value 80h is written to the address E2h.

(3-1) Valid Channel (CH[2:0])

Assigned to the Lower Three Bits Bit2 Through Bit0.

The valid channel CH[2:0] indicates, in binary, the target channel for which the button has become valid by being simultaneously pressed or by being long pressed. The initial value thereof is (000) in binary.

(3-2) Valid Button Data (SIMUL)

Assigned to the lower fifth bit, i.e., Bit4. The “valid button data” indicates whether or not the “valid channel data” is asserted. Specifically, “1” indicates the asserted state (ON state), and “0” indicates the negated state (OFF state). The initial value is “0”.

(3-3) Long Press Valid State Data (CONTINU)

Assigned to the most significant bit, i.e., Bit7. “1” indicates that the “valid channel data” is continuously asserted (held in the ON state) for a predetermined time period or more. “0” indicates the negated state. The initial value is 0.

(4) Address 40h to 47h

Offset Correction Value (OFFSET)

The “offset correction values” for the channels 0 through 7 are stored at these addresses.

After the completion of the initial sequence after the start-up operation, the control circuit 200 performs offset correction such that the capacitance value of each sensor capacitor Ci matches the center value of 8 bits (256 dynamic range), i.e., 128, in the state in which no operations have been performed. The offset values thus obtained in this step are stored at the addresses 40h through 47h, in increments of channels.

(5) Address 60h/61h

Gesture Speed Judgment (GES_VEL)

A total of 12 bits, composed of all 8 bits at the address 60h and the lower 4 bits at the address 61h, store data which indicates the time period taken to input a gesture. The data is represented by the count value obtained using the internal clock. The available count value ranges from 0 to 4095.

(6) Address 62h

Gesture Direction Judgment (GES_DIR)

(6-1) Gesture direction A (DIR_A)

Assigned to the least significant bit, i.e., Bit0. When a forward direction gesture is detected, “1” is stored.

### (6-2) Gesture Direction B (DIR_B)

Assigned to the lower second bit, i.e., Bit1. When a reverse direction gesture is detected, “1” is stored.

(7) Address E2h

Gesture Clear (GES_CLR)

The most significant bit, i.e., Bit7 of the address E2h, is used to clear the values of GES_VEL and GES_DIR. Once a gesture is detected, the values of BTN_STATE, GES_VEL, and GES_DIR are held. Accordingly, after acquisition of the values, in order to detect the next gesture, the values are cleared by this register. When “1” is stored, these values are cleared. When “0” is stored, the values are automatically returned to zero.

(8) Address E3h

Gesture Function Setting (GES_CTL)

As described above, the channels which can be assigned for detecting a gesture are the four channels 0, 2, 4, and 6. Enable data EN[3] through EN[0], which each determine whether or not the corresponding channel is set to a target for which a gesture should be detected, are written to the lower four bits Bit3 through Bit0 of GES_CTL. The enable data EN[0] through EN[3] correspond to the channels 0, 2, 4, and 6. For example, in a case in which EN[0:3] is set to (1110), the channels 0, 2, and 4 are set to the target channels for which a gesture should be detected, and the channel 6 is eliminated as a detection target. The initial value is (1111).

The lower fifth bit Bit4 of the GES_CTL stores the data for setting the gesture detection mode MODE. When MODE is set to 1, the detection mode is set to the strict detection mode. When MODE is set to 0, the detection mode is set to the redundant mode.

(9) Address E4h

Gesture Clock Setting (GES_CLK)

The clock used for gesture detection is generated by dividing the clock generated by the CR oscillator of the clock generating unit 216. The gesture clock setting GES_CLK stores 2-bit data G_DIV[1:0] for setting the dividing ratio. The gesture clock settings G_DIV=(00), (01), (10), and (11) represent the dividing ratios r=1, 2, 4, and 8, respectively. The initial value of G_DIV is (00).

With the frequency of the CR oscillator as f, the gesture sampling interval ts is represented by the Expression ts=1/(f/(2·16·16)·r). For example, in a case in which the frequency of the CR oscillator is 1.1 MHz, the gesture sampling intervals ts are 0.46 ms, 0.93 ms, 1.86 ms, and 3.72 ms. The ON/OFF state of each button that corresponds to a channel for which a gesture should be detected is monitored at gesture sampling intervals ts, thereby judging whether or not a gesture has been detected.

(10) Address E5h

Gesture Timeout Value Setting (GES_TIMEOUT)

8-bit data TO[7:0] is stored for setting the gesture maximum judgment time period tmsx. The gesture maximum judgment time period tmsx is represented by the Expression tmax=ts×TO×16 [s]. A gesture which is input over a time period that exceeds tmax is not detected. In other words, when a series of gestures is executed over a time period within the gesture maximum judgment time period tmax, a gesture detection flag is set to the ON state. The initial value is (11111111).

(11) Address EDh

Soft Reset (RESET)

The soft reset (RESET) is used to reset the device. When “1” is set, reset processing is executed. After the execution of the reset processing, the soft reset (RESET) is automatically returned to 0. In this case, the values of all the internal registers are initialized. Accordingly, the host processor must write the settings again when the state is returned, in the same way as after the power supply is turned on.

(12) Address EEh

Soft Calibration (CALIB)

The soft calibration (CALIB) is used to execute sensor offset canceling processing at a desired point in time. When is written, the calibration processing is executed. After the execution of the calibration processing, the soft calibration (CALIB) is automatically returned to 0. After the gain of the capacitance detection unit 202 is adjusted, the soft calibration (CALIB) is always set to 1.

(13) Address EFh

Setting Completion/Detection Start (DONE)

When “1” is written to this address after the initial setting items have been written, the flow enters a detection step. In a case in which the settings are to be set again after the detection starts, the host processor transmits commands in the order of soft reset, setting, and detection start.

(14) Address F0h

Sensor Channel Setting (SENS_CH)

The sensor channel setting (SENS_CH) is a register for defining the channels to be used as the sensors. The most significant bit, i.e., Bit7, corresponds to the sensor input SIN7, and the least significant bit, i.e., Bit0, corresponds to the sensor input SIN0. When “1” is set, the sensor is enabled, and when “0” is set, the sensor is disabled. The initial value is (00000000), which disables all the channels.

(15) Address F2h

LED Channel Setting (LED_CH)

The LED channel setting (LED_CH) is used for defining the channels to be used as the LED drivers. The lower four bits Bit0 through Bit3 store the data which indicates whether or not the LEDs connected to the 8th pin, 10th pin, 12th pin, and 14th pin are to be used. The upper four bits are not used. When “1” is set, the LED is enabled, and when “0” is set, the LED is disabled. The initial value is (00000000).

(16) Address F3h

Idle Mode Cancel Target Channel Setting (IDLE_CH)

The idle mode cancel target channel setting (IDLE_CH) is a register for defining the channels which are switched from the idle mode to the normal mode. Bit7 through Bit0 thereof correspond to the sensor inputs SIN7 through SIN0, respectively. When “1” is set, the switch is enabled, and when “0” is set, the switch is disabled. The initial value thereof is (11111111).

(17) Address F5h

Sensor Link Driven Target Channel Setting (LED_LINK)

The sensor link driven target channel setting (LED_LINK) is a register which determines, for each channel connected to an LED, whether the LED emits light according to the operation applied to the button, or emits light according to an instruction from the host processor. The lower four bits Bit3 through Bit0 correspond to the LED3 through LED0, respectively. When “1” is set, the LED emits light according to the operation applied to the button. When “0” is set, the LED emits light according to data DLED received from the host processor. The initial value of the lower four bits is (1111). The upper four bits are not used.

(18) Address F6h

Long Press Continuous Time/Chattering Canceling Sampling Count Setting (TIMES)

The upper four bits Bit7 through Bit4 of the address F6h store data CONT_T[3:0] which sets the long press judgment time period. A decimal number value ranging between 0 and 15 is set for the CONT_T[3:0]. The long press judgment time period is obtained by multiplying the value of CONT_T by a predetermined time unit. When “0” is set, the long press judgment function is disabled.

The lower four bits Bit3 through Bit0 of the address F6h store the chattering canceling sampling count, i.e., sampling SAMP[3:0]. The consecutive button operation level which is equal to or smaller than the sampling count set by this data is ignored. When “0” is set, the sampling function is disabled.

(19) Address F7h

Button OFF-ON Judgment Second Threshold Value (TH_ON2)

The Button OFF-ON judgment second threshold value (TH_ON2) stores data for setting a threshold value used to judge whether or not the state of the sensor output is to be switched from the button-off state to the button-on state. The target sensor channels are specified by the register TH_ON2_CH described later. The 8-bit sensor output value (register SENS_DATA) is compared with (128+TH_ON2[6:0]). If the sensor output value is greater than the threshold value, judgment is made that the switch operation is valid. The initial value thereof is (00100000).

(20) Address F8h

Button OFF-ON Judgment Second Threshold Value Application Channel Setting (TH_ON2_CH)

The button OFF-ON judgment second threshold value application channel setting TH_ON2_CH is used to set the channels to which the value set for the aforementioned TH_ON2 is applied as a threshold value for the judgment of whether or not the state of the sensor output is to be switched from the button-off state to the button-on state. When “1” is set, TH_ON2 is used, and when “0” is set, TH_ON is used.

(21) Address FAh

Simultaneously pressed button selection, intermittent driving enable, and state undetected period of validity setting: CMD

### (21-1) Simultaneously Pressed Button Judgment Rule Selection Register (SIMUL_SEL)

The simultaneously pressed button judgment rule selection register (SIMUL_SEL) is used to set the rule based upon which a high-priority channel is determined in a case in which multiple switches have been pressed at the same time. When “1” is set, the channel having a higher sensor level is set to a higher-priority channel. When “0” is set, the highest priority level is set for the channel which was pressed first.

### (21-2) Intermittent Driving Enable (INTERMIT_EN)

The intermittent driving enable (INTERMIT_EN) corresponds to the upper fourth bit BIT4, and is used to select whether or not the intermittent driving operation is performed in the idle mode. When “1” is set, the intermittent driving function is enabled. When “0” is set, the intermittent driving function is disabled. The initial value thereof is 1.

### (21-3) State Undetected Period of Validity Setting (IDLE_T[3:0])

The state undetected period of validity setting (IDLE_T[3:0]) corresponds to the lower four bits Bit3 through Bit0. The time period before the mode transits to the idle mode is determined by multiplying the value of the IDLE_T by a predetermined time unit. When the value thus set is 0, the function of allowing the mode to transit to the idle mode is disabled.

(22) Address Fbh

Gain Setting/Filter Function (FILTER)

The gain setting/filter function (FILTER) is used to set the noise filter function.

(22-1) Gain Setting (GAIN[2:0])

Assigned to the upper three bits. The gain setting (GAIN[2:0]) is used for eight levels of gain adjustment.

(22-2) Filter Enable (FILTER_EN)

The Filter enable (FILTER_EN) is a register used to enable or disable the noise filter function. Assigned to the upper fourth bit, i.e., BIT4. When “1” is set, the noise filter function is enabled, and when “0” is set, the noise filter function is disabled. The initial state is set to the disabled state.

(22-3) Noise Filter Responsiveness (DELTA[3:0])

The noise filter responsiveness (DELTA[3:0]) is used to set the responsiveness count Δ which is used when the noise filter function is enabled. Assigned to the lower four bits, i.e., Bit3 through Bit0.

(23) Address FCh

Button OFF-ON Judgment Threshold Value (TH_ON)

The lower seven bits, i.e., Bit 6′ through Bit0 are used. The button OFF-ON judgment threshold value (TH_ON) stores the data for setting a threshold value used for judgment of whether or not the state of the sensor output is to be switched from the button-off state to the button-on state. This data is applied to the channels other than the channels designated by the register TH_ON2_CH. The 8-bit sensor output value (register SENS_DATA) is compared with (128+TH_ON[6:0]). If the sensor output value is greater than the threshold value, judgment is made that the switch operation is valid. The initial value thereof is (00100000).

(24) Address FDh

Button ON-OFF Judgment Threshold Value (TH_OFF)

The lower seven bits, i.e., Bit6 through Bit0 are used. The button ON-OFF judgment threshold value (TH_OFF) stores the data for setting a threshold value used for judgment of whether or not the state of the sensor output is to be switched from the button-on state to the button-off state. The 8-bit sensor output value (register SENS_DATA) is compared with (128+TH_OFF[6:0]). If the sensor output value is smaller than the threshold value, judgment is made that the switch operation is invalid. The initial value thereof is (00000001).

(25) Address FEh

LED Port Data (DLED)

The LED port data (DLED) stores the data for controlling the ON/OFF state of each LED in a case in which the operation of the LED is not linked to the operation of the sensor. The lower four bits Bit3 through Bit0 indicate the states of the diode channels LED3 through LED0, respectively. When “1” is set, the LED is turned on. When “0” is set, the LED is turned off.

### Second Embodiment

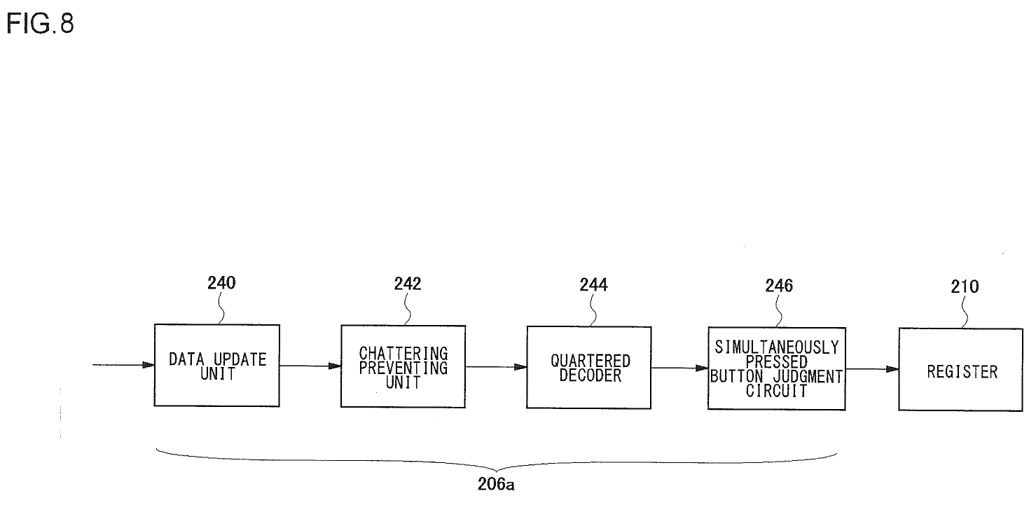

FIG. 8 is a block diagram which shows a configuration of a data correction processing unit 206a of a control circuit according to a second embodiment. The data correction processing unit 206a includes a data update unit 240, a chattering preventing unit 242, a quartered-signal decoder 244, and a simultaneously pressed button judgment circuit 246.

The data update unit 240 receives the data of each channel from the A/D converter 204 which is an upstream component, and updates the data thus received at every sampling. The chattering preventing unit 242 functions in the same way as with the noise filter 230 and/or the chattering canceling unit 232 shown in FIG. 6. The chattering preventing unit 242 outputs digital data that corresponds to the capacitance of each channel.

Next, description will be made regarding the function of the quartered-signal decoder 244, with reference to an arrangement in which multiple buttons (switches) are provided on a casing of a cellular phone terminal or the like. In a case in which a single sensor capacitor is assigned to each button, judgment is made based upon the capacitance of the corresponding sensor capacitor whether each button is in the ON state or the OFF state. Accordingly, if a second button, which is an undesired adjacent button, is pressed when the user presses the first button, it is difficult to judge which button the user desired to press. In order to solve such a problem, in the present embodiment, multiple sensor capacitors (divided sensor capacitors) are assigned to each button.

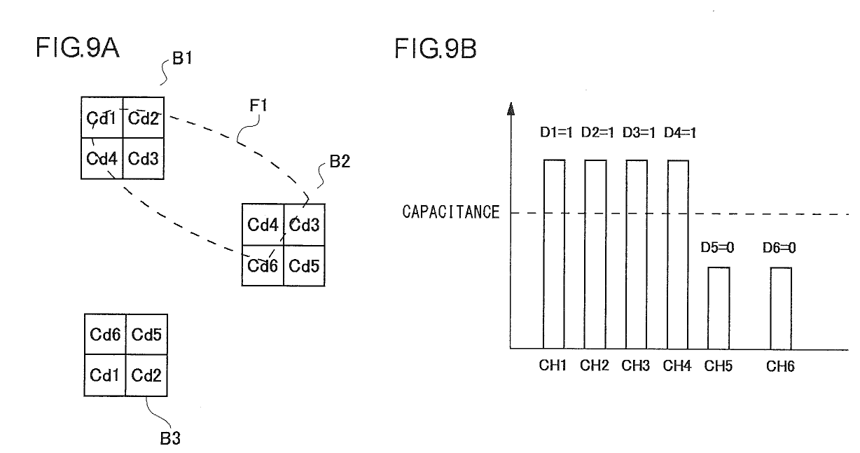

FIG. 9A and FIG. 9B are diagrams which show the layout of the divided sensor capacitors and the threshold-based judgment using the divided sensor capacitors. FIG. 9A shows three buttons (switches) B1 through 33. Furthermore, four divided sensor capacitors Cd are assigned to each button. That is to say, a total of twelve divided sensor capacitors are provided. Each of the multiple divided sensor capacitors is assigned to one of the multiple channels of the control circuit 200. It should be noted that the divided sensor capacitors assigned to the same button are preferably assigned to different channels. That is to say, it is preferable that the divided sensor capacitors Cd assigned to the same channel are not assigned to the same button.

Furthermore, it is preferable that two divided sensor capacitors Cd that are assigned to the same channel are not arranged adjacent to one another. The phrase “not arranged adjacent to one another” as used here means that the two divided sensor capacitors are not the most neighboring vertically, horizontally, or obliquely. The term “most neighboring” refers to two divided sensor capacitors with no divided sensor capacitor introduced between them. Accordingly, for example, in FIG. 9A, it can be said that the capacitors Cd2, Cd3, and Cd4 provided to the button B1 are each arranged adjacent to the capacitor Cd1 provided to the button B1. Furthermore, it can be said that the capacitor Cd4 provided to the button 32 and the capacitors Cd5 and Cd6 provided to the button B3 are not each arranged adjacent to the capacitor Cd1 provided to the button B1.

In a case in which judgment is made with respect to the three buttons based upon the 6-channel sensor inputs of the control circuit 200, two divided sensor capacitors are assigned to each channel. The capacitance detection unit 202, which is a component upstream of the data correction processing unit 206, measures the total capacitance of the two divided sensor capacitors for each channel. In FIG. 9A, the reference numerals assigned to each divided sensor capacitor Cd denote the identification number of the corresponding channel.

That is to say, the quartered-signal decoder 244 receives, as input data, the data which represents the total capacitance for each channel. A comparison unit (not shown) included in the quartered-signal decoder 244 compares the combined capacitance with a predetermined threshold value for each channel, and converts the comparison results into binary digital signals which indicate whether each channel is in the ON state or the OFF state.

Now, let us suppose that the region indicated by the broken line F1 shown in FIG. 9A is pressed by the user's finger. In this state, the user desires to switch the button B1 to the ON state. However, a part of the adjacent button B2 is also pressed. FIG. 9B shows the capacitance for each channel in this situation. In a case in which the capacitance of a channel exceeds a threshold level TH, judgment is made that the channel is in the ON state.

A decoder (not shown) included in the quartered-signal decoder 244 decodes, in increments of channels, the binary digital signals output from the comparison unit, and judges whether or not each switch is in the ON state or the OFF state. The decoder decodes the data Dⱼ (j=1 to 6) which indicate the ON/OFF state of each channel CHj (j=1 to 6).

The decoder judges whether the ith button Bi is in the ON state or the OFF state by judging whether or not the data of all the multiple channels assigned to this channel matches the ON state. When all the data matches the ON state, judgment is made that the button is in the ON state.

That is to say, in a case in which the channels k, l, m, and n are assigned to the ith button Bi, the state of the button Bi is represented by the following Expression.

Bi=Dk·Dl·Dm·Dn

Here, “·” represents the logical AND. It should be noted that the assignment of the data logical values may be modified. In a case of such a modification, an appropriate logical computation other than the logical AND should be used.

In the example shown in FIG. 9A, the channels k=1, l=2, m=3, and n=4 are assigned to the first button B1. Accordingly, when all the channels 1, 2, 3, and 4 indicate the ON-state, i.e., when D1=D2=D3=D4=1, judgment is made that the button B1 is in the ON state.

In the same way, the channels k=3, l=4, m=5, and n=6 are assigned to the second button B2. In the example shown in FIGS. 9A and 9B, D3=D4=1, and D5=D6=0, and accordingly, judgment is made that the button B2 is in the OFF state. The channels k=1, l=2, m=5, and n=6 are assigned to the second button B3. In this case, D1=D2=1, and D5=D6=0, and accordingly, judgment is made that the button B3 is in the OFF state.

As described above, with the control circuit 200b according to the second embodiment, multiple divided sensor capacitors are assigned to a single button. Furthermore, the decoding processing is performed for the judgment values for the divided sensor capacitors. In other words, the sensor capacitor provided to a single button is divided into multiple capacitors, and the sensor capacitors thus divided are assigned to different judgment units, following which the decoding processing is performed for the judgment results in increments of channels. As a result, such an arrangement provides improved precision as compared with conventional judgment methods in which a signal sensor capacitor is assigned to each button.

Description has been made in FIGS. 9A and 9B regarding an arrangement in which the number of divided sensor capacitors is greater than the number of channels. However, in a case in which the number of channels is greater, an arrangement may be made in which each divided sensor capacitor may be assigned to a single channel.

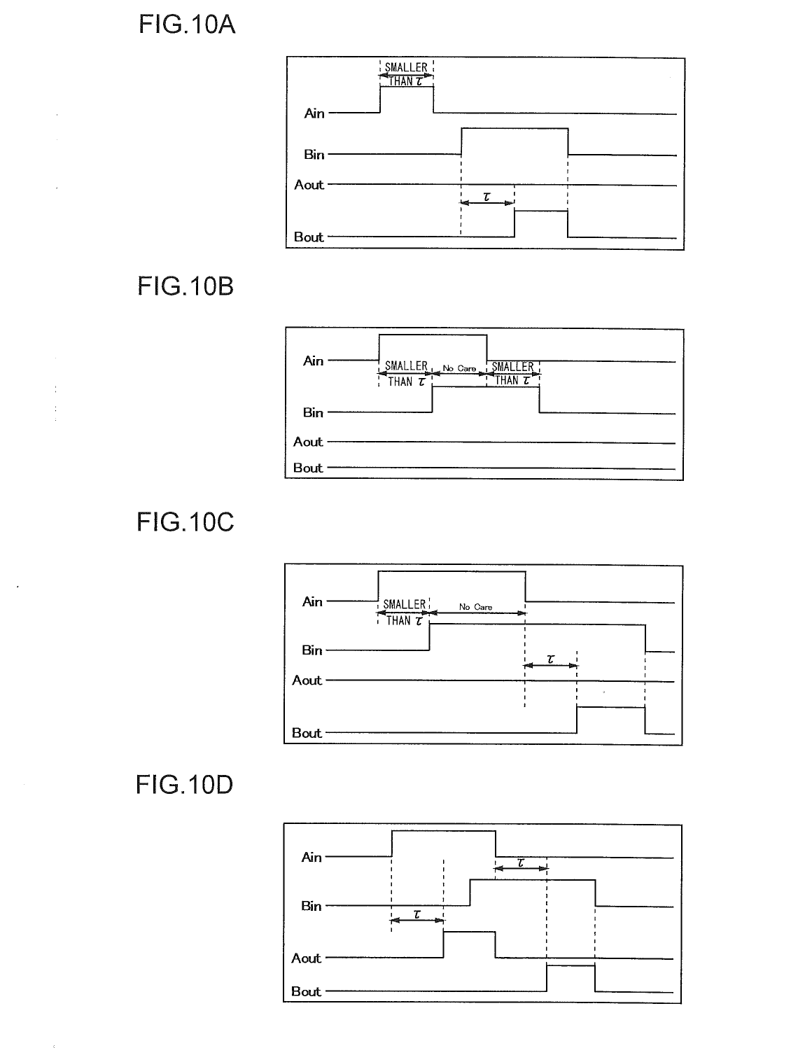

The quartered-signal decoder 244 judges which button has been switched on from among the buttons B1 through B3. The data which indicates the ON/OFF state of each button is output to the simultaneously pressed button judgment circuit 246 which is a downstream component. In a case in which multiple buttons have been pressed at the same time, the simultaneously pressed button judgment circuit 246 performs processing based upon the following criteria. FIGS. 10A through 10D show the judgment result obtained by the simultaneously pressed button judgment circuit 246. The 2-channel input data Ain and Bin and the output data Aout and Bout which are the corresponding judgment results are shown.

(1) Judgment Criterion 1

A predetermined judgment time period τ is set for the simultaneously pressed button judgment circuit 246. When a given button continuously indicates the ON state over the judgment time period τ, the data which indicates that the given button is in the ON state is output after the expiration of the judgment time period. As shown in FIG. 10A, the input data Ain is switched to the OFF state after a time period which is smaller than the judgment time period τ. Accordingly, the output data Aout is maintained in the OFF state. The input data Bin is maintained at the high level which indicates the ON state over a time period which is equal to or greater than the judgment time period τ. In this case, the output data Bout is switched to the high-level state after the expiration of the judgment time period τ after the input data Bin is switched to the high-level state.

(2) Judgment Criterion 2

In a case in which given input data has been switched to the high-level state, and different input data is then switched to the high-level state before the expiration of the judgment time period τ, judgment is made that these input data are both invalid.

(3) Judgment Criterion 3

When single input data is switched to the low-level state after the multiple input data are switched to the high-level state, and accordingly, when only a single input is available, judgment is made with respect to the available channel according to the judgment criterion 1 after the point in time when this single input becomes available.

As shown in FIGS. 10B and 10C, in a case in which the input data Ain has been switched to the high-level state, and following which the input data Bin is switched to the high-level state before the expiration of the judgment time period τ, judgment is made that both inputs are invalid.

In FIG. 10B, subsequently, the input data Ain is switched to the low-level state. However, the input data Bin is switched to the low-level state before the expiration of the judgment time period τ. Accordingly, the output data Bout is maintained in the low-level state according to the judgment criterion 3.

In FIG. 10C, single input data Ain of the two input data is switched to the low-level state, following which the input data Bin is maintained at the high level for the judgment time period τ or more. Accordingly, after the expiration of the judgment time period τ, the output data Bout is switched to the high-level state.

(4) Judgment Criterion 4

In a case in which given input data is switched to the high-level state after judgment has been made that different input data is valid, and accordingly, in a case in which multiple channels are in the high-level state, a high priority level is set for the channel which was judged to be valid first, and the channel which was switched to the high-level state later is ignored. Immediately after the channel which was judged to be valid first has been switched to the low-level state, valid channel judgment is made according to the judgment criterion 1.

In FIG. 10D, first, the input data Ain is switched to the high-level state. After the expiration of the judgment time period τ, the output data Aout is switched to the high-level state. Subsequently, the input data Bin is also switched to the high-level state. However, the input data Ain has already been judged to be valid, and accordingly, the high level of the input data Bin is ignored. Subsequently, immediately after the input data Ain is switched to the low-level state, and the output data Aout is switched to the low level state, judgment is made with respect to the input data Bin. After the expiration of the judgment time period τ, judgment is made that the channel B is valid, which switches the output data Bout to the high-level state.

In a case in which the number of channels is three or more, the third channel and above are subjected to the processing in the same way as for the second channel.

Description has been made regarding the present invention with reference to the embodiments using specific terms. However, description has been made in the embodiments regarding only the mechanisms and applications of the present invention. Various modifications and changes in the layout may be made without departing from the scope and spirit of the present invention defined by appended claims.

What is claimed is:

1. An electrostatic sensor comprising:
a plurality of switches;
a plurality of sensor capacitors assigned to each of the plurality of switches; and
a control circuit which judges based upon the capacitance values of the plurality of sensor capacitors whether each of the plurality of switches is in the ON state or the OFF state,
wherein each of the plurality of sensor capacitors is assigned to one of a plurality of channels,
and wherein the control circuit comprises
a capacitance detection unit which detects the combined capacitance of the sensor capacitors assigned to each of the plurality of channels,
a comparison unit which compares, in increments of channels, the combined capacitance detected by the capacitance detection unit with a predetermined threshold value, and converts the comparison results into binary digital signals in increments of channels, and
a decoder which decodes the binary digital signals with respect to the plurality of channels output from the comparison unit, and judges whether each switch is in the ON state or the OFF state.

2. An electrostatic sensor according to claim 1, wherein, when the combined capacitance is greater than the predetermined threshold value for all the plurality of channels assigned to a given switch, the decoder judges that the given switch is in the ON state.

3. An electrostatic sensor according to claim 1, further including a simultaneously pressed button judgment circuit which receives data that indicates the ON/OFF state of each of the plurality of switches,
wherein, when data that corresponds to a given switch continuously indicates the ON state for a predetermined judgment time period, the simultaneously pressed button judgment circuit judges that the ON state of the switch is valid.

4. An electrostatic sensor according to claim 3, wherein, when data that corresponds to a given switch indicates the ON state before the expiration of the judgment time period after data that corresponds to a different switch indicates the ON state, the simultaneously pressed button judgment circuit judges that the ON states of both of the two switches are invalid.

5. An electrostatic sensor according to claim 3, wherein, when data that corresponds to one of two switches, both of which indicate the ON state, transits to the state that indicates the OFF state, the simultaneously pressed button judgment circuit checks whether or not data that corresponds to the other switch continuously indicates the ON state for the judgment time period.

6. An electrostatic sensor according to claim 3, wherein, even when data that corresponds to a given switch indicates the ON state in a time period during which judgment is made that the ON state of a different switch is valid, the simultaneously pressed button judgment circuit judges that the ON state of that given switch is invalid.
